(19) United States
(12) Patent Application Publication
(10) Pub. No.: US 2022/0043358 A1
(43) Pub. Date: Feb. 10, 2022

(54) METHOD FOR PRODUCING OR SETTING A PROJECTION EXPOSURE APPARATUS

(71) Applicant: Carl Zeiss SMT GmbH, Oberkochen (DE)

(72) Inventor: Rolf Freimann, Aalen (DE)

(21) Appl. No.: 17/382,577

(22) Filed: Jul. 22, 2021

(30) Foreign Application Priority Data
Aug. 4, 2020 (DE) 102020209784.4

(51) Int. Cl. G03F 7/20

(52) U.S. Cl. CPC G03F 7/70125; G03F 7/70266; G03F 7/70308

(57) ABSTRACT

A projection exposure apparatus includes a light source, an illumination system, and a projection lens. A method for producing or setting the projection exposure apparatus includes determining a first imaging property to be optimized. Optimizing the first imaging property includes optimizing the setting of the illumination system and/or the structure of the mask and/or at least one first adjustable optical element of the projection lens with respect to the shape of one of its at least one optically effective surfaces or with respect to the optical effect for the purposes of setting an optimized wavefront of the working light. Optimizing the illumination system, mask and/or optical element of the projection lens is implemented so that a further manipulator of the projection exposure apparatus for manipulating the wavefront is set in the central position of its manipulation range during the optimization of the first imaging property.

### CROSS-REFERENCE TO RELATED APPLICATION

This application claims benefit under 35 U.S.C. § 119 to German Application No. 10 2020 209 784.4, filed Aug. 4, 2020. The contents of this application is hereby incorporated by reference in its entirety.

### FIELD

The present disclosure relates to a method for producing or setting a projection exposure apparatus which includes a light source, an illumination system, and a projection lens and which is used to image structures of a mask, and relates for example to a method for optimizing imaging properties.

### BACKGROUND

In microlithography, projection exposure apparatuses are used to produce microstructured or nanostructured components for microelectronics or microsystems technology. On account of advancing miniaturization of corresponding components, it is desirable to reliably image structures with ever smaller dimensions in a suitable manner. Accordingly, use is already made of projection exposure apparatuses that are operated using extreme ultraviolet light (EUV light) in order to further improve the resolution of corresponding projection exposure apparatuses.

Moreover, optimization methods relating to the setting of suitable illumination settings of illumination systems of projection exposure apparatuses and to the design of the structure of masks are furthermore known, in order to be able to reliably image structures with the relatively small structure widths and relatively small structure spacings. Such optimization methods are known under the heading of resolution enhancement techniques (RET) and are described in U.S. Pat. Nos. 9,588,438 B2 and 9,041,908 B2, the disclosure of which is herewith expressly and fully incorporated herein.

These documents describe, inter alia, source mask optimization (SMO) methods, a source mask lens optimization (SMLO) method, a source mask pupil optimization (SMPO) method, a mask wavefront optimization (MWO) method, a source mask wavefront optimization (SMWO) method, and a source mask polarization wavefront optimization (SMPWO) method, which are also used in the method of the present disclosure.

### SUMMARY

The disclosure seeks to provide an improvement in the imaging properties of projection exposure apparatuses, and a corresponding method that is relatively easily and relatively reliably implementable with a reasonable outlay.

In an aspect, the disclosure provides a method for producing or setting a projection exposure apparatus. The projection exposure apparatus includes a light source, an illumination system, and a projection lens used to image structures of a mask. The projection lens includes a plurality of optical components which can be adjusted in order to set imaging properties of the projection exposure apparatus. The method includes determining a first imaging property which should be optimized. For the purpose of optimizing the first imaging property, the setting of the illumination system and/or the structure of the mask and/or at least one first adjustable optical element of the projection lens are optimized with respect to the shape of one of its at least one optically effective surfaces or with respect to the optical effect for the purposes of setting an optimized wavefront of the working light. Optimizing the illumination system, mask and/or optical element of the projection lens is implemented in such a way that at least one further manipulator of the projection exposure apparatus for manipulating the wavefront is set in the central position of its manipulation range during the optimization of the first imaging property.

By way of example, the first imaging property can include the optimization of the correction of mask-dependent aberrations, for example the optimization of the imaging of critical structure constituents or the optimization of the resolution of certain structures or the optimization of the correction of aberrations due to structure widths or structure spacings.

Initially, the setting of the illumination system is optimized in order to optimize the first imaging property. As an alternative or in addition thereto, the structure of the mask can likewise be optimized in order to optimize the first imaging properties. Furthermore, provision is alternatively or additionally made for an optimization of the wavefront of the working light by at least one first adjustable optical element of the projection lens, wherein the first adjustable optical element of the projection lens is optimized with respect to the shape of one of its at least one optically effective surfaces or with respect to its optical power.

Initially, simulations and/or calculations can be carried out for this optimization of the first imaging properties, with use being able to be made of various methods from the is prior art. In this case, it is possible to use corresponding resolution enhancements technologies (RET), as described in the US patents cited above. For example, use can be made of methods for optical proximity correction (OPC), application of phase-shift masks (PSM), application of sub resolution assist features (SRAF), source mask optimization (SMO), source mask lens optimization (SMLO), source mask pupil optimization (SMPO), mask wavefront optimization (MWO), source mask wavefront optimization (SMWO), and source mask polarization wavefront optimization (SMPWO).

Moreover, the illumination system and/or mask and/or an optical element of the projection lens can be optimized with respect to the first imaging property in such a way that, furthermore, at least one manipulator, optionally a plurality or all of the manipulators of the projection exposure apparatus for manipulating the wavefront, which do not serve to set the illumination system and/or the first adjustable optical element of the projection lens, are set to the central position of their respective manipulation range during the optimization of the first imaging properties. Consequently, the illumination system and/or mask and/or a first adjustable optical element of the projection lens can be optimized with the boundary condition that additional manipulators are set into the central position of the manipulation range. What this achieves is that, following the optimization of the first imaging properties, the maximum manipulation range can be available for a further manipulation of the wavefront for the purposes of correcting further imaging properties. For example, if additional aberrations are introduced during the operation of the projection exposure apparatus, for example as a result of optical elements heating up, this renders it possible to correct said additional aberrations by way of further manipulation of the wavefront.

The at least one optical element of the projection lens which can be used to optimize the wavefront during the optimization of the first imaging properties can be a mirror, the shape of the optically effective surface, i.e., the mirror surface, thereof being altered. For example, the corresponding optical element can be a deformable mirror, which has actuators which facilitate a change in shape of the mirror surface. Furthermore, it is also possible for the optical element of the projection lens used to manipulate the wavefront to be a refractive optical element, the shape of the optically effective surface and/or the refractive index of which being altered, for example by local heating or the like.

If a deformable mirror is used during the optimization of the first imaging property, the deformable mirror or the corresponding actuators can be set in such a way that, following the setting of the shape of the optically effective surface, i.e., the mirror surface, for the optimized first imaging property, the actuators are present in a central position in relation to the deformation range such that continuing deformation of the deformable mirror is possible with a maximum actuation range of the actuators.

The further manipulators of the projection exposure apparatus for manipulating the wavefront, which are set in the central position of the manipulation range during the optimization of the first imaging properties, can be further optical elements which can be altered over a movement range in terms of their position and/or alignment for the purposes of manipulating the wavefront. In the case of an EUV projection exposure apparatus, these can be further mirrors of the projection lens, for example, which are alterable in terms of their position and/or alignment.

In order to be able to set the further manipulators in a central position of the manipulation range during the optimization of the first imaging property, the method can furthermore include a step of capturing all manipulators and determining the entire manipulation range of the manipulators.

The manipulation range of the further manipulators can be determined for various aberrations, for example in accordance with various Zernike polynomials.

### BRIEF DESCRIPTION OF THE FIGURES

The accompanying drawings are purely schematic.

In the drawings:

FIG. 1 is an illustration of an EUV projection exposure apparatus;

FIG. 2 is an illustration of a flowchart of a method;

FIG. 3 is an illustration of a deformable mirror, as can be used in the projection exposure apparatus of FIG. 1;

FIG. 4 is an illustration of the intensity distribution in a pupil plane for an illumination setting for the EUV projection exposure apparatus of FIG. 1;

FIG. 5 is an illustration of a portion of a mask with a sub resolution assist structure, as is used in the projection exposure apparatus of FIG. 1; and

FIG. 6 is an illustration of the manipulation ranges for various aberrations as per Zernike polynomials for a projection exposure apparatus of FIG. 1.

### DESCRIPTION OF EXEMPLARY EMBODIMENTS

Further aspects, characteristics and features of the present disclosure will become evident from the following detailed description of the exemplary embodiments. However, the disclosure is not limited to these exemplary embodiments.

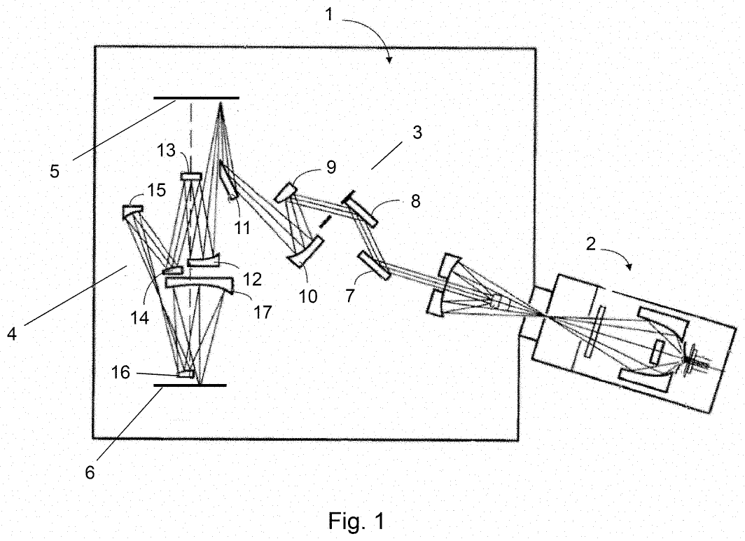

FIG. 1 shows an illustration of an EUV projection exposure apparatus 1, for the production or setting of which the present disclosure can be used. The EUV projection exposure apparatus 1 illustrated in FIG. 1 includes a light source unit 2 and an illumination system 3 and projection lens 4, by which the structures of a mask 5 are imaged in reduced fashion on a wafer 6. The illumination system 3 includes a field facet mirror 7 and a pupil facet mirror 8, and a first telescope mirror 9 and a second telescope mirror 10 and a deflection mirror 11, by which the EUV light of the light source 2 is prepared in order to illuminate the mask 5.

The projection lens 4 includes six mirrors 12 to 17, wherein one of these mirrors can be embodied as first adjustable optical element, for example in the form of a deformable mirror, such that a desired wavefront of the EUV light can be generated in the projection lens 4 by the setting of the surface form of the mirror such that optimized imaging of the mask 5 on the wafer 6 is facilitated.

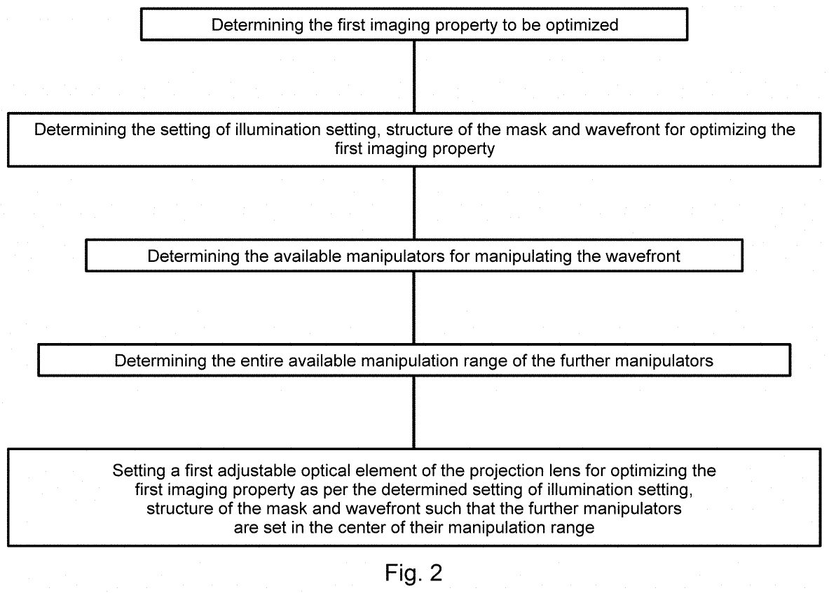

FIG. 2 shows the sequence of a method according to the disclosure for setting the projection exposure apparatus 1.

Initially, a first imaging property to be optimized is determined, for example imaging of certain structures of the mask to be optimized or the correction of so-called proximity effects when imaging adjacent structures on the mask, as in the case of the optical proximity correction (OPC).

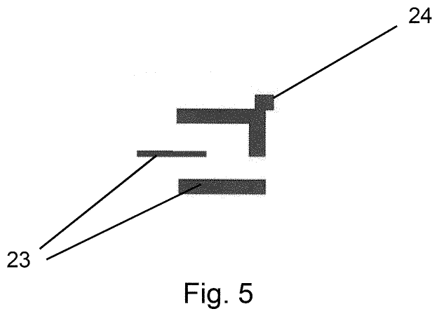

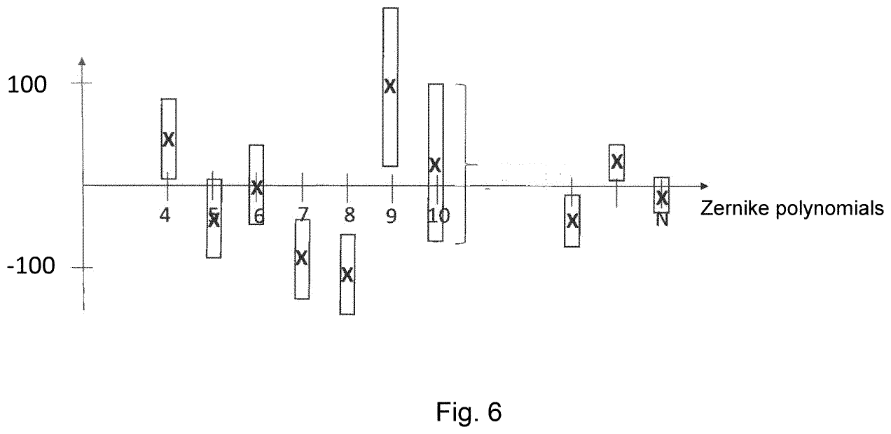

To this end, simulation and calculations initially determine what setting of an illumination setting should be undertaken in the illumination system, as illustrated in FIG. 4, for example, and what structures, as illustrated in FIG. 5, for example, the mask should have in order to facilitate an optimization of the first imaging properties or to bring about the correction of so-called proximity effects. Moreover, the possible look of the optimal wavefront for such an optimization of the first imaging property is determined.

After simulating and calculating the settings of illumination setting, structure of the mask, and the wavefront, the available manipulators for manipulating the wavefront are determined and the entire available manipulation range of the manipulators is calculated.

Subsequently, for a first adjustable optical element of the projection lens, the corresponding setting of this optical element is undertaken taking account of the determined setting of illumination setting, structure of the mask and desired wavefront, in such a way that, firstly, the optimization of the first imaging properties is ensured by the setting of the first adjustable optical element and the wavefront manipulation generated thereby and that, secondly, further manipulators such as further adjustable optical elements present in the projection exposure apparatus are set in the center of their manipulation range.

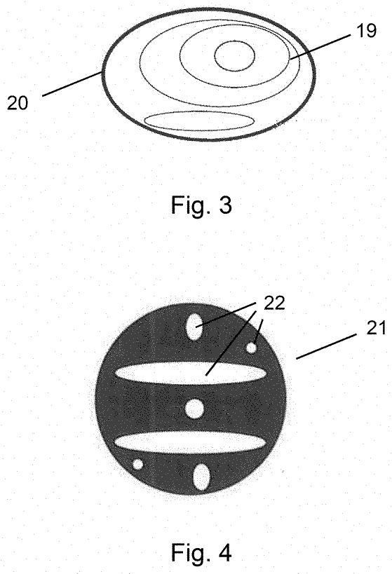

By way of example, a deformable mirror 20, as illustrated in FIG. 3, can find use as first adjustable optical element. The deformable mirror 20 can be deformed in such a way that elevations and/or depressions arise at the mirror surface, as is illustrated by way of the contour lines 19 in FIG. 3, for example. Using this deformable mirror 20 and the setting of the corresponding mirror surface, it is possible to manipulate the wavefront in such a way that it corresponds to the determined setting of the wavefront for the optimization of the first imaging properties, i.e., for example, for correcting proximity effects when imaging adjacent structures of the mask. Moreover, the deformable mirror can also be constructed or set in such a way that the actuators for setting the desired deformation are in the central position of their actuation range such that further deformations of the deformable mirror are possible with a maximum actuation range.

At the same time, further manipulators of the projection exposure apparatus and, for example, of the projection lens are set in the central position of their manipulation range such that maximal manipulation ranges are ensured in these, too. By way of example, if the mirror 14 is embodied as a deformable mirror 20 in the EUV projection exposure apparatus 1, for example, the remaining mirrors 12 and 15 to 17 can be varied in terms of their position and/or alignment in order thus to generate a manipulation of the wavefront.

According to some embodiments of the disclosure, the first adjustable optical element, i.e., the deformable mirror 14, 20, is set on the basis of the determination of the entire available manipulation range of the manipulators such that the remaining mirrors 12 and 15 to 17 are in the center of their manipulation range such that a maximum of further manipulation options is provided for the further operation of the projection exposure apparatus and the correction of further imaging properties, for example if adaptations to the wavefront are involved on account of mirrors heating up, or the like. If the manipulation range is given by the position and/or alignment range of the mirrors 12 and 15 to 17, the center of the manipulation range accordingly is at the central position of the respective position and/or alignment range.

Instead of a deformable mirror, which can be deformed in a certain way over the entire mirror surface by way of a multiplicity of actuators, use can also be made of a mirror whose mirror surface is shaped in accordance with the result of the present disclosure and is fixed accordingly. Accordingly, the shape in the case of such a mirror is set prior to the operation and the correction of further imaging properties during the operation of the projection exposure apparatus can be undertaken by the setting of further manipulators. By contrast, in the case of a deformable mirror as a first adjustable optical element, the corresponding adaptation can be undertaken in variable fashion at any time desired.

For different aberrations, FIG. 6 shows by way of an appropriate cross the different manipulation ranges as per the Zernike polynomials and the position of the set wavefront in the respective manipulation ranges after setting the projection exposure apparatus according to the present disclosure. As is evident from FIG. 6, what the setting as per the present disclosure achieves is that a large manipulation range still is available for setting further imaging properties or for correcting further aberrations which may arise during the operation of the projection exposure apparatus. While the totality of the further available manipulators are set in such a way in the exemplary embodiment shown that the imaging properties or aberrations to be manipulated therewith overall are each located in a central position of the manipulation range, an individual further manipulator can also be provided or individual further manipulators can also each be provided for certain settings of imaging properties or corrections for aberrations in a corresponding central position of the manipulation range.

Although the present disclosure has been described in detail on the basis of the exemplary embodiments, it is obvious to a person skilled in the art that the disclosure is not restricted to these exemplary embodiments but rather that modifications are possible, such that individual features can be omitted or different types of combinations of features can be implemented, without departing from the scope of protection of the appended claims. For example, the present disclosure covers all combinations of the individual features shown in the various exemplary embodiments, such that individual features described only in connection with one exemplary embodiment can also be used in other exemplary embodiments or in non-explicitly shown combinations of individual features.

### LIST OF REFERENCE SIGNS

1 Projection exposure apparatus

2 Light source unit

3 Illumination system

4 Projection lens

5 Reticle or mask

6 Wafer

7 Field facet mirror

8 Pupil facet mirror

9 First telescope mirror

10 Second telescope mirror

11 Deflection mirror

12 First mirror

13 Second mirror

14 Third mirror

15 Fourth mirror

16 Fifth mirror

17 Sixth mirror

19 Contour lines

20 Deformable mirror

21 Pupil

22 Intensity maximum

23 Structure parts

24 Sub resolution assist feature (SRAF)

What is claimed is:

1. A method of producing or setting a projection exposure apparatus comprising a first manipulator configured to manipulate a wavefront of working light of the projection exposure apparatus, a light source, an illumination system, and a projection lens configured to image structures of a mask, the projection lens comprising a plurality of optical components which are adjustable to set imaging properties of the projection exposure apparatus, the method comprising:
i) optimizing a setting of the illumination system to optimize a first imaging property, and/or optimizing a structure of the mask to optimize the first imaging property, and/or optimizing a shape of an optically effective surface of an adjustable optical element of the projection lens to optimize the wavefront of the working light of the projection exposure apparatus, and/or optimizing an optical power of the adjustable optical element of the projection lens to optimize the wavefront of the working light of the projection exposure apparatus,
wherein i) further comprises setting the first manipulator in a central position of its manipulation range.

2. The method as claimed in claim 1, wherein:
i) comprises optimizing the shape of the optically effective surface of the adjustable optical element to optimize the wavefront of the working light of the projection exposure apparatus, and/or optimizing the optical power of the adjustable optical element to optimize the wavefront of the working light of the projection exposure apparatus; and
the adjustable optical element comprises a mirror.

3. The method of claim 2, further comprising, during use of the projection exposure apparatus or before use of the projection exposure apparatus, altering a shape of the optically effective surface of the mirror.

4. The method as claimed in claim 2, wherein i) comprises setting the optically effective surface of the mirror in a central position of its deformation range.

5. The method of claim 1, wherein:
i) comprises optimizing the shape of the optically effective surface of the adjustable optical element to optimize the wavefront of the working light of the projection exposure apparatus, and/or optimizing the optical power of the adjustable optical element to optimize the wavefront of the working light of the projection exposure apparatus; and
the adjustable optical element comprises a refractive optical element.

6. The method of claim 5, further comprising altering a shape of the optically effective surface of the refractive optical element and/or altering a refractive index of the refractive optical element.

7. The method of claim 1, wherein:
the projection exposure apparatus comprises a plurality of manipulators configured to manipulate the wavefront of the working light; and
i) comprises, for each manipulator, setting the manipulator in a central position of its manipulation range.

8. The method of claim 1, wherein the projection exposure apparatus comprises a second manipulator configured so that its position and/or its alignment is alterable over a movement range to manipulate the wavefront of the working light.

9. The method of claim 1, wherein i) comprises optimizing the first imaging property, and optimizing the first imaging property comprises optimizing a correction of mask-dependent aberrations.

10. The method of claim 1, wherein:
i) comprises optimizing the first imaging property; and
optimizing the first imaging property comprises optimizing a member selected from the group consisting of an imaging of critical structure constituents, a resolution of certain structures, a correction of aberrations due to structure widths, and a correction of aberrations due to structure spacings.

11. The method of claim 1, wherein:
i) comprises optimizing the first imaging property; and
optimizing the first imaging property comprises using at least one process selected from the group consisting of resolution enhancement technologies (RET), optical proximity correction (OPC), application of phase-shift masks (PSM), application of sub resolution assist features (SRAF), source mask optimization (SMO), source mask lens optimization (SMLO), source mask pupil optimization (SMPO), mask wavefront optimization (MWO), source mask wavefront optimization (SMWO), and source mask polarization wavefront optimization (SMPWO).

12. The method of claim 1, wherein:
the projection exposure apparatus comprises a plurality of further manipulators; and
the method further comprises, for each of the plurality of further manipulators, capturing the manipulator and determining an entire manipulation range of the manipulator.

13. The method of claim 12, wherein determining the manipulation range for each of the further manipulators comprises using aberrations.

14. The method of claim 12, wherein determining the manipulation range for each of the further manipulators comprises using aberrations in accordance with Zernike polynomials.

15. The method of claim 12, wherein, for each of the plurality of further manipulators, the further manipulator is set in its central position of its manipulation range as per Zernike polynomials for a plurality of aberrations during i).

16. The method of claim 1, wherein i) comprises optimizing a setting of the illumination system to optimize a first imaging property.

17. The method of claim 1, wherein i) comprises optimizing a structure of the mask to optimize the first imaging property.

18. The method of claim 1, wherein i) comprises optimizing the shape of the optically effective surface of the adjustable optical element of the projection lens to optimize the wavefront of the working light of the projection exposure apparatus.

19. The method of claim 1, wherein i) comprises optimizing the optical power of the adjustable optical element of the projection lens to optimize the wavefront of the working light of the projection exposure apparatus.

20. The method of claim 1, wherein i) comprises at least two members selected from the group consisting of:
optimizing the setting of the illumination system to optimize the first imaging property;
optimizing the structure of the mask to optimize the first imaging property;
optimizing the shape of the optically effective surface of the adjustable optical element of the projection lens to optimize the wavefront of the working light of the projection exposure apparatus; and
optimizing the optical power of the adjustable optical element of the projection lens to optimize the wavefront of the working light of the projection exposure apparatus.
